(19) United States
(12) Patent Application Publication
(10) Pub. No.: US 2017/0107614 A1
(43) Pub. Date: Apr. 20, 2017

(54) Multi-Step Atomic Layer Deposition Process for Silicon Nitride Film Formation

(71) Applicant: Veeco ALD Inc., Fremont, CA (US)

(72) Inventors: Sang In LEE, Lost Altos Hills, CA (US); Yeong Kwan KIM, Dublin, CA (US); Jungyup KIM, Palo Alto, CA (US)

(21) Appl. No.: 15/292,034

(22) Filed: Oct. 12, 2016

Related U.S. Application Data
(60) Provisional application No. 62/242,943, filed on Oct. 16, 2015.

(51) Int. Cl. C23C 16/34; C23C 16/455

(52) U.S. Cl. CPC C23C 16/345; C23C 16/45525

(57) ABSTRACT

One or more silicon nitride layers are deposited onto a substrate by exposing the surface of the substrate to radicals to activate the surface of the substrate. A silicon-containing first precursor with a high sticking coefficient is injected onto the substrate. A second precursor including molecules each having at least two Si atoms is injected onto the substrate. The first precursor has a higher sticking coefficient than the second precursor. The substrate is treated with nitrogen radicals N* to form multiple layers of silicon nitride per radical exposure. This results in high-quality silicon nitride films with high deposition rate.

### CROSS-REFERENCE TO RELATED APPLICATION

This application claims the benefit of U.S. Provisional Application No. 62/242,943, filed on Oct. 16, 2015, which is incorporated by reference herein in its entirety.

### BACKGROUND

1. Field of Art

The disclosure relates to depositing silicon nitride films on a substrate using two silicon-containing precursors and nitrogen radicals.

2. Description of the Related Art

An atomic layer deposition (ALD) is a thin film deposition technique for depositing one or more layers of material on a substrate. ALD uses two types of chemicals, one a source precursor and the other a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor.

Silicon nitride (SiₓN_{y}) is a stable material commonly used in the fabrication of integrated circuit devices. When deposited as a film, it can effectively act as a barrier layer to prevent underlying structures from being damaged by moisture permeation or from being oxidized by diffusion of oxygen into the underlying structure. Silicon nitride (SiₓN_{y}), including silicon carbonitride (SiCN), is also very stable. Due to such qualities, silicon nitride has also been used to prevent oxidation of the bottom of high aspect ratio trench structures.

ALD can be used to deposit conformal silicon nitride and/or silicon carbonitride layers across the trench patterned substrate for good step coverage. However, silicon nitride, including silicon carbonitride, can be difficult to synthesize and ALD can be a slow process that can take an extended amount of time or many repetitions before a layer of desired thickness can be obtained.

### SUMMARY

Embodiments relate to depositing one or more silicon nitride or silicon carbonitride layers onto a substrate with conformal step coverage and high deposition rate. A first precursor is injected onto the surface of the substrate. The first precursor includes Si and has a first sticking coefficient. A second precursor including molecules each having at least two Si atoms is injected onto the surface of the substrate to deposit the one or more silicon nitride layers onto the substrate by reaction between the first precursor injected onto the substrate and the second precursor. The second precursor has a second sticking coefficient lower than the first sticking coefficient. The substrate is then treated with nitrogen radicals N* formed from a first gas after injecting the second precursor. The nitrogen radicals N* formed from the first gas interact with the first precursor and the second precursor to deposit the one or more silicon nitride layers onto the substrate.

In one embodiment, the first precursor includes tris(dimethylamino)silane (3DMAS), bis(diethylamino)silane (BDEAS), bis(tertiery-butylamino)silane (BTBAS), diisopropylaminosilane (DiPAS) or di(sec-butylamino)silane (DSBAS).

In one embodiment, the second precursor includes bis(trimethylsilyl)carbodiimde (BTSCDI), hexamethyldisilazane (HIVIDS), trisilylamine (TSA), Trisilylamino-diethylsilane (TSADES), Bis(dimethylaminomethylsilyl) (methylsilyl) amine (BDMAMS-MSA: C₇H₂₅N₃Si₃), Bis(dimethylaminomethylsilyl) (trimethylsilyl) amine (BDMAMS-TMSA: C₉H₂₉N₃Si₃), disilane (Si₂H₆), or trisilane (Si₃H₈).

Embodiments also relate to an apparatus for depositing one or more silicon nitride layers onto a substrate. The apparatus includes a first injector, a moving actuator, a second injector, a first radical reactor, and a controller. The first injector has a first reaction chamber opening towards a surface of a substrate. The second injector is on the path of the relative movement, and has a second reaction chamber opening towards the surface of the substrate. The first radical reactor is also on the path of relative movement. The controller causes the first injector to inject a silicon-containing first precursor onto the substrate to cause adsorption of silicon atoms of the first precursor onto the surface of the substrate. The first precursor has a first sticking coefficient. The moving actuator causes a relative movement between the substrate and the first injector. The controller further causes the second injector to inject a second precursor including molecules each having at least two Si atoms onto the surface of the substrate to deposit the one or more silicon nitride layers onto the substrate by reaction between the first precursor injected onto the substrate and the second precursor. The second precursor has a second sticking coefficient lower than the first sticking coefficient. The controller further causes the first radical reactor to generate and inject nitrogen radicals N* formed from a first gas onto the substrate after injecting the second precursor. The nitrogen radicals N* formed from the first gas interact with the first precursor and the second precursor to deposit the one or more silicon nitride layers onto the substrate.

In one embodiment, the apparatus includes a second radical reactor on the path of the relative movement. The controller further causes second radical reactor to generate and inject nitrogen radicals N* generated from a second gas onto the substrate after injecting the second precursor and before injecting the nitrogen radicals N* generated from the first gas to deposit one or more intermediate silicon nitride layers onto the substrate. The concentration of nitrogen species in the second gas is higher than the concentration of nitrogen species in the first gas.

### BRIEF DESCRIPTION OF THE DRAWINGS

FIG. 1 is a cross-sectional diagram of a linear deposition device for performing atomic layer deposition, according to one embodiment.

FIG. 2 is a perspective view of a linear deposition device, according to one embodiment.

FIG. 3 is a perspective view of a rotating deposition device for performing atomic layer deposition, according to one embodiment.

FIG. 4A is a perspective view of reactors in a deposition device of FIG. 1, according to one embodiment.

FIG. 4B is a perspective view of reactors in a deposition device of FIG. 1, according to one embodiment.

FIG. 4C is a perspective view of reactors in a deposition device of FIG. 1, according to one embodiment.

FIG. 5A is a flowchart illustrating a method of depositing one or more silicon nitride layers onto a substrate, according to one embodiment.

FIG. 5B is a flowchart illustrating a method of depositing one or more silicon nitride layers onto a substrate having an additional process of treating the substrate with hydrogen radicals, according to one embodiment.

FIG. 5C is a flowchart illustrating a method of depositing one or more silicon nitride layers onto a substrate, according to one embodiment.

FIG. 5D is a flowchart illustrating a method of depositing one or more silicon nitride layers onto a substrate with an additional process of treating substrate with radicals, according to one embodiment.

FIGS. 6A through 6F are conceptual diagrams illustrating materials deposited on the substrate when the substrate undergoes processing steps for performing ALD using di(sec-butylamino)silane (DSBAS) as the first precursor and trisilylamine (TSA) as the second precursor, according to one embodiment.

FIGS. 7A through 7E are conceptual diagrams illustrating materials deposited on the substrate when the substrate undergoes processing steps for performing ALD using di(sec-butylamino)silane (DSBAS) as the first precursor and bis(trimethylsilyl)carbodiimde (BTSCDI) as the second precursor, according to one embodiment.

FIG. 8A is a flowchart illustrating a method of depositing one or more silicon nitride layers onto a substrate, according to one embodiment.

FIG. 8B is a flowchart illustrating a method of depositing one or more silicon nitride layers onto a substrate, according to another embodiment.

FIGS. 9A through 9F are conceptual diagrams illustrating materials deposited on the substrate when the substrate undergoes processing steps for performing ALD using di(sec-butylamino)silane (DSBAS) as the first precursor and trisilylamine (TSA) as the second precursor, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to performing an ALD process to deposit one or more layers of silicon nitride layers, including silicon carbonitride layers, with conformal step coverage and increased deposition rate. A first precursor with a high sticking coefficient and a second precursor including molecules each having at least two Si atoms are injected onto the surface of the substrate to form silicon compounds on the surface of the substrate. The sticking coefficient of a molecule (atom) is the ratio of number of molecules (atoms) that adsorb to a surface to the total number of molecules (atoms) that impinge upon the surface for a given period of time. Using such a first precursor with a high sticking coefficient increases the probability of adsorption of the first precursor onto the surface of the substrate. Meanwhile, the second precursor with at least two Si atoms reacts with the adsorbed first precursor to form at least two molecules of silicon compounds on the surface of the substrate. Subsequently, the substrate containing the silicon compounds is treated with nitrogen radicals N* to form multiple layers of silicon nitride per radical exposure. The combination of the first precursor, second precursor, and nitrogen radicals results in high quality silicon nitride layers with increased deposition rate.

### Linear Deposition Device

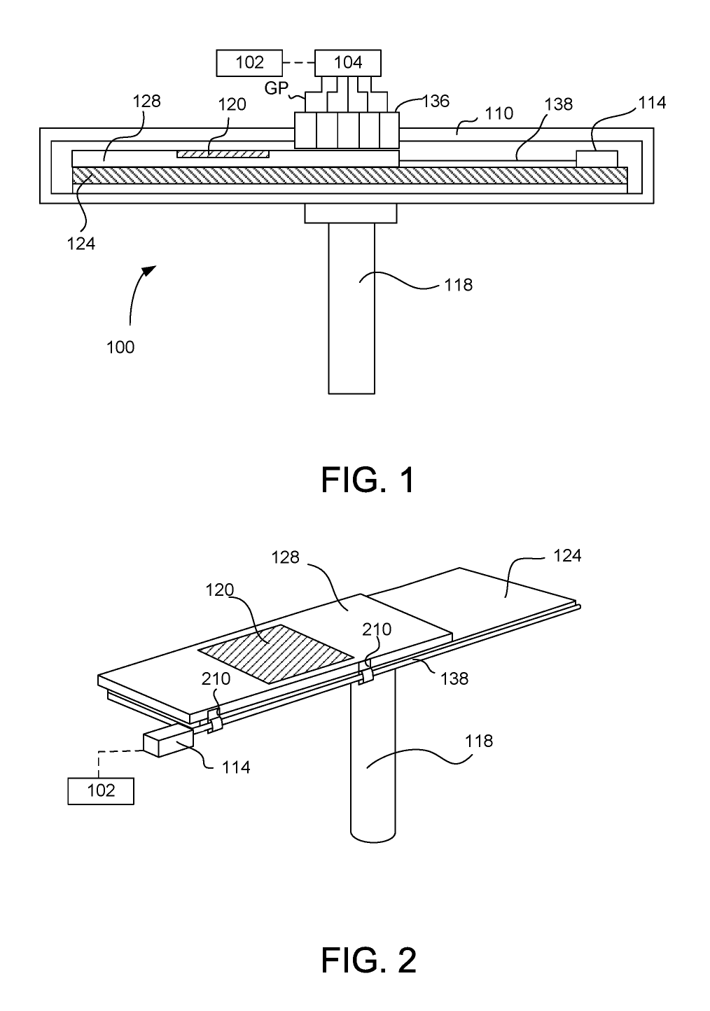

Figure (FIG.) 1 is a cross-sectional diagram of a linear deposition device 100 for performing an ALD process, according to one embodiment. FIG. 2 is a perspective view of the linear deposition device 100 (without chamber walls to facilitate explanation), according to one embodiment. The linear deposition device 100 may include, among other components, a controller 102, a gas valve assembly 104, a support pillar 118, a process chamber 110, and one or more reactors 136. The reactors 136 may include one or more of injectors and one or more radical reactors that inject gas and radicals of gas onto the surface of the substrate. Each of the injectors injects purge gas and silicon-containing precursors onto the substrate 120. Each of the radical reactors generate and inject nitrogen radicals N* onto the substrate 120. The controller 102 is a computing device that controls the operating conditions of the linear deposition device 100. The controller 102 may adjust the gas injected into the reactors 136 (e.g., the pressure, flow rate, temperature and mixture ratio) and controls plasma generation conditions (e.g., the voltage or wave pattern of signals applied to electrodes of the radical reactors) to adjust the concentration of radicals in the radical reactors. To control the flow of gas into the reactors 136, the controller 102 sends control signals (shown by a dashed line in FIG. 1) to the gas valve assembly 104 The gas valve assembly 104 provides gas as determined by the control signals to the reactors 136 via gas lines GP.

The process chamber 110 enclosed by the walls may be maintained in a vacuum state to prevent contaminants from affecting the deposition process. The process chamber 110 contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

In one embodiment, the linear deposition device 100 includes a moving actuator configured to cause a relative movement between the substrate 120 and the reactors 136. The moving actuator includes the motor 114 and the extended bar 138. The susceptor 128 is secured to one or more brackets 210 that move across the extended bar 138 with screws formed thereon. The brackets 210 have corresponding screw threads formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. In other words, the brackets 210 convert the rotational motion of the extended bar 138 into linear motion parallel to the extended bar 138. The controller 102 controls the speed and rotation direction of the motor 114. By doing so, the speed and the direction of the linear movement of the susceptor 128 can be controlled along a path of relative movement. The use of a motor 114 and the extended bar 138 is merely an example of the moving actuator causing relative movement between the susceptor 128 and the reactors 136. Alternatively or additionally, the moving actuator moves the susceptor 128 by various other means (e.g., gears, rack, and/or pinion at the bottom, top, or side of the susceptor 128). Instead of (or in addition to) moving the susceptor 128 relative to the reactors 136, the moving actuator may move the reactors 136 relative to the susceptor 128.

### Rotating Deposition Device

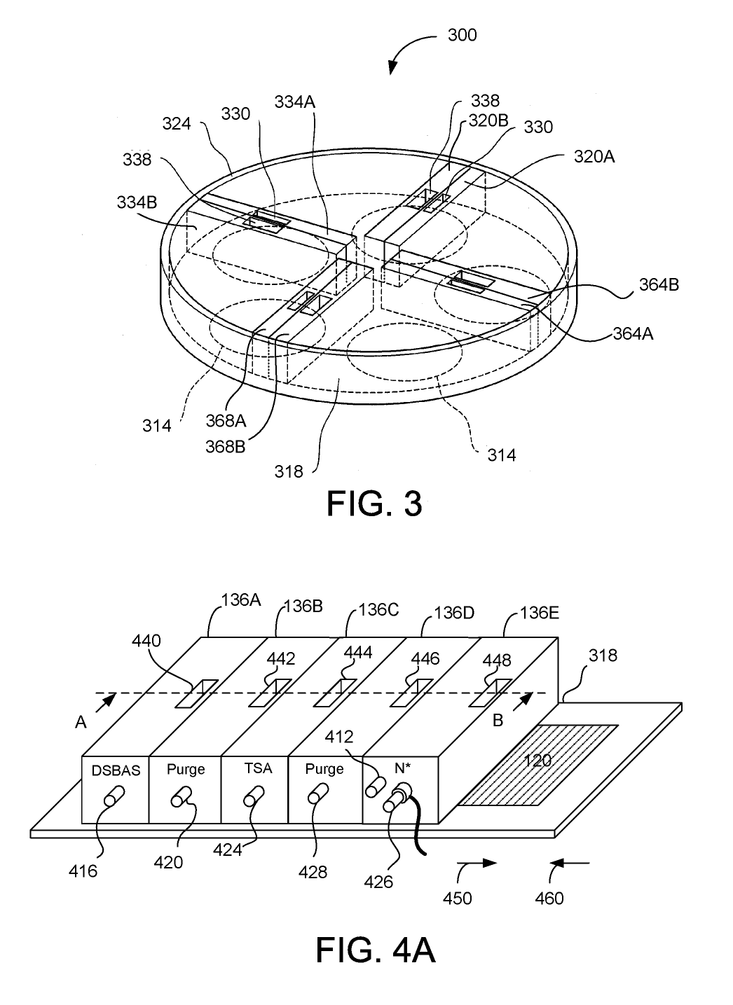

FIG. 3 is a perspective view of a rotating deposition device 300, according to one embodiment. Instead of (or in addition to) using the linear deposition device 100 of FIG. 1, the rotating deposition device 300 may perform the deposition process. The rotating deposition device 300 may include, among other components, a controller (not shown), a gas valve assembly (not shown), reactors 320A, 320B, 334A, 334B, 364A, 364B, 368A, 368B (collectively referred to as reactors 320, 334, 364, and 368), a susceptor 318, and a container 324 enclosing these components. The controller controls injection of gas (e.g., pressure, flow rate, temperature and mixture ratio of gas) injected into the reactors 320, 334, 364, and 368 as well as control the rotating direction and speed of the susceptor 318. A set of reactors (e.g., 320A and 320B) of the rotating deposition device 300 correspond to the reactors 136 of the linear deposition device 100, as described above with reference to FIG. 1. The susceptor 318 secures the substrates 314 in place. The reactors 320, 334, 364, and 368 are placed above the substrates 314 and the susceptor 318. The rotating deposition device 300 may include a moving actuator to cause relative rotation between the susceptor 318 and the reactors 320, 334, 364, and 368. The relative rotation subjects the substrates 314 to different processes corresponding to the different reactors 320, 334, 364, and 368 as the substrates 314 follow a circular path of relative movement. The rotating deposition device 300 may include a motor and connective components (not shown) to transfer rotational motion from the motor to the susceptor 318.

One or more of the reactors 320, 334, 364, or 368 are connected to gas pipes (not shown) to provide source precursor, reactor precursor, purge gas, and/or other materials.

The materials provided by the gas pipes may be (i) injected onto the substrate 314 directly by the reactors 320, 334, 364, or 368, (ii) after mixing in a chamber inside the reactors 320, 334, 364, or 368, or (iii) after conversion into radicals by plasma generated within the reactors 320, 334, 364, or 368. After the materials are injected onto the substrate 314, the redundant materials may be exhausted through outlets 330 or 338. The interior of the rotating deposition device 300 may also be maintained in a vacuum state.

Although the following example embodiments are described primarily with reference to the reactors 136 in the linear deposition device 100, the same principles and operations can be applied to the rotating deposition device 300 or other types of deposition device.

### Example Reactors

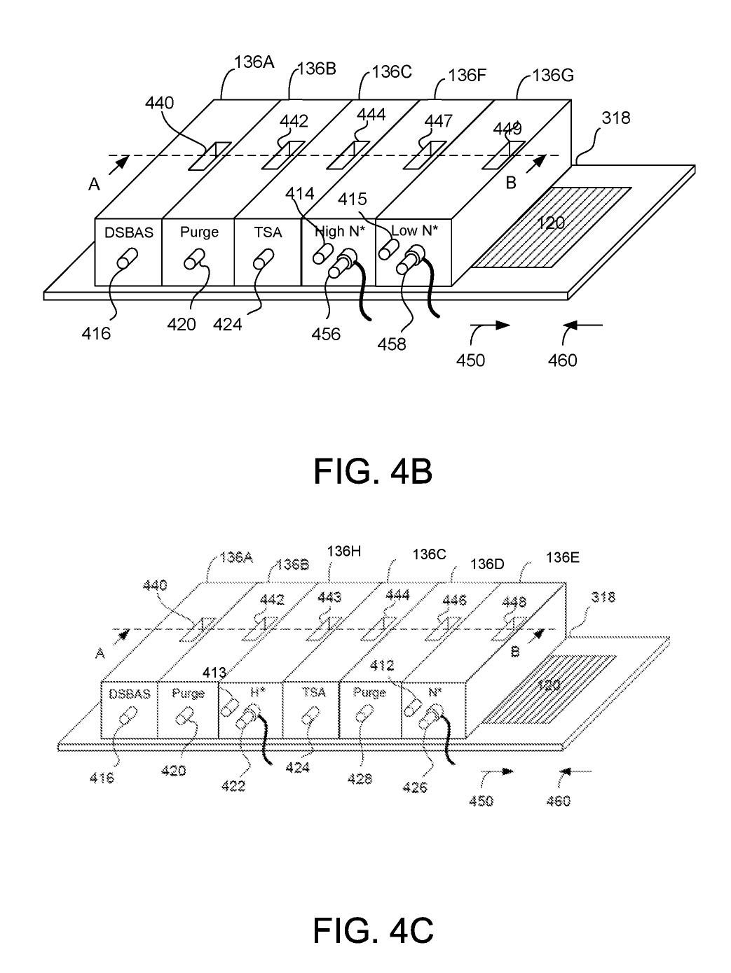

FIG. 4A is a perspective view of reactors 136A through 136E (collectively referred to herein as the “reactors 136”) in the deposition device 100 of FIG. 1, according to one embodiment. In the embodiment of FIG. 4A, the reactors 136A through 136E are placed in tandem adjacent to each other. In other embodiments, the reactors 136A through 136E may be placed at a distance from each other. As the substrate 120 moves from the left to the right (as shown by arrow 450), the substrate 120 is sequentially injected with materials by the reactors 136A through 136E to deposit a layer of material onto the substrate 120. Instead of (or in addition to) the substrate 120 being moved relative to the reactors 136, the reactors 136 may be moved relative to the substrate 120 (e.g., from right to left while injecting materials).

In one embodiment, after moving the substrate 120 from the left to the right, the substrate 120 may be moved from right to left (as shown by arrow 460) to expose the substrate 120 and the deposited material thereon to a different sequence of materials compared to moving the substrate 120 from left to right. In another embodiment, the substrate 120 is repeatedly exposed to the same sequence of materials. The exposure of the substrate 120 to the same sequence of materials may be accomplished by using the rotating deposition device 300 or shutting off the gas and radicals while the substrate 120 is moving in the direction shown by arrow 460 and turning back on the gas and radicals while the substrate 120 is moving in the direction shown by arrow 450.

The reactors 136A, 136B, 136C and 136D are injectors for injecting gas or a mixture of gas onto the substrate 120 received via pipes 416, 420, 424 and 428, respectively. Excess gas remaining after injection onto the substrate 120 is exhausted via exhaust portions 440, 442, 444 and 446.

The reactor 136E is a radical reactor that generates radicals of gas or a gas mixture received from one or more sources. The gas or gas mixtures are injected into the reactor 136E via pipe 412, and are converted into radicals within the reactor 136E by applying voltage across an electrode 426 and a body of the radical reactor 136E. The radicals are injected onto the substrate 120, and remaining radicals and/or gas reverted to inactive state are discharged from the radical reactor 136E via exhaust 448.

In one embodiment, the injectors 136A, 136B, 136C and 136D inject, respectively, a silicon-containing first precursor (e.g., di(sec-butylamino)silane), a purge gas (e.g., Ar or N₂ gas), a silicon-containing second precursor including molecules each having at least two Si atoms (e.g., trisilylamine or bis(trimethylsilyl)carbodiimde) and a purge gas. The radical reactor 136E generates nitrogen radicals N* from gas (e.g., N₂, N₂+Ar, N₂+H₂, N₂+NH₃) provided through the pipe 412. As a result of injecting these materials in sequence, a silicon nitride layer is deposited on the substrate 120.

FIG. 4B is a perspective view of reactors 136A through 136C, 136F and 136G in the deposition device 100 of FIG. 1, according to another embodiment. In the embodiment of FIG. 4B, the reactors 136D and 136E in the embodiment of FIG. 4A are replaced with reactors 136F and 136G.

The reactor 136F is a radical reactor. Gas or gas mixtures are injected into the reactor 136F via pipe 414, and are converted into radicals within the reactor 136F by applying a voltage across an electrode 456 and a body of the radical reactor 136F. The radicals are injected onto the substrate 120, and remaining radicals and/or gas reverted to inactive state are discharged from the radical reactor 136F via exhaust 447. The reactor 136G is also a radical reactor. Gas or gas mixtures are injected into the reactor 136G via a pipe 415, and are converted into radicals within the reactor 136G by applying a voltage across an electrode 458 and a body of the radical reactor 136G.

In one embodiment, the injectors 136A, 136B and 136C inject, respectively, a silicon-containing first precursor (e.g., di(sec-butylamino)silane), a purge gas (e.g., argon gas Ar as an inert gas or nitrogen gas N₂ in a neutral state) and a silicon-containing second precursor including molecules each having at least two Si atoms (e.g., trisilylamine or bis(trimethylsilyl)carbodiimde). The radical reactor 136F generates high concentration nitrogen radicals N* generated from a first gas (e.g., N₂, N₂+Ar, N₂+H₂, N₂+NH₃) provided through the pipe 414. The radical reactor 136G generates a lower concentration of nitrogen radicals N* generated from a second gas (e.g., N₂+H₂, N₂+Ar, NH₃, NH₃+H₂, NH₃+N₂, NH₃+Ar) provided through the pipe 415. The first gas has a higher molar fraction or concentration of nitrogen species (e.g., N₂) than the second gas. As a result of injecting these materials in sequence, a silicon nitride layer is deposited on the substrate 120. In another instance, the substrate 120 moves in the opposite direction (e.g., right to left), and is injected first with the lower concentration of nitrogen radicals N* from the radical reactor 136G and then the high concentration of nitrogen radicals N* from radical reactor 136F.

FIG. 4C is a perspective view of reactors 136A through 136E, and 136H in the deposition device 100 of FIG. 1, according to one embodiment. In the embodiment of FIG. 4C, the reactor 136H is added to the embodiment of FIG. 4A.

The reactor 136H is a radical reactor. Gas or gas mixtures are injected into the reactor 136H via pipe 413, and are converted into radicals within the reactor 136H by applying a voltage across an electrode 422 and a body of the radical reactor 136H. The radicals are injected onto the substrate 120, and remaining radicals and/or gas reverted to inactive state are discharged from the radical reactor 136F via exhaust 443.

In one embodiment, the injectors 136A, 136B, 136C and 136D inject, respectively, a silicon-containing first precursor (e.g., di(sec-butylamino)silane), a purge gas (e.g., Ar or N₂ gas), a silicon-containing second precursor including molecules each having at least two Si atoms (e.g., trisilylamine or bis(trimethylsilyl)carbodiimde) and a purge gas. The radical reactor 136E generates nitrogen radicals N* from first gas (e.g., N₂, N_{z}+Ar, N₂+H₂, N₂+NH₃) provided through the pipe 412. The radical reactor 136H generates hydrogen radicals H* or nitrogen radicals N* from a second gas (e.g. H₂, H₂+Ar, N₂+H₂, NH₃, N₂+NH₃) provided through the pipe 413 to convert the silicon-containing first precursor (e.g., di(sec-butylamino)silane) to a more reactive source precursor by reacting the ligands of the first precursor with only H* radicals or mixture of radicals generated from the second gas that has a molar fraction of hydrogen than the molar fraction of hydrogen of the first gas.

### Deposition of Silicon Nitride Layers

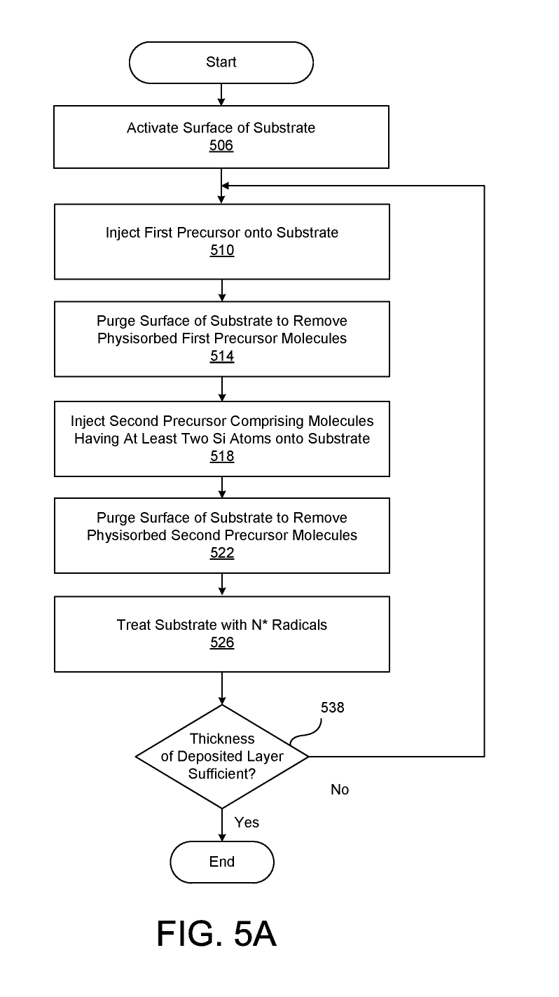

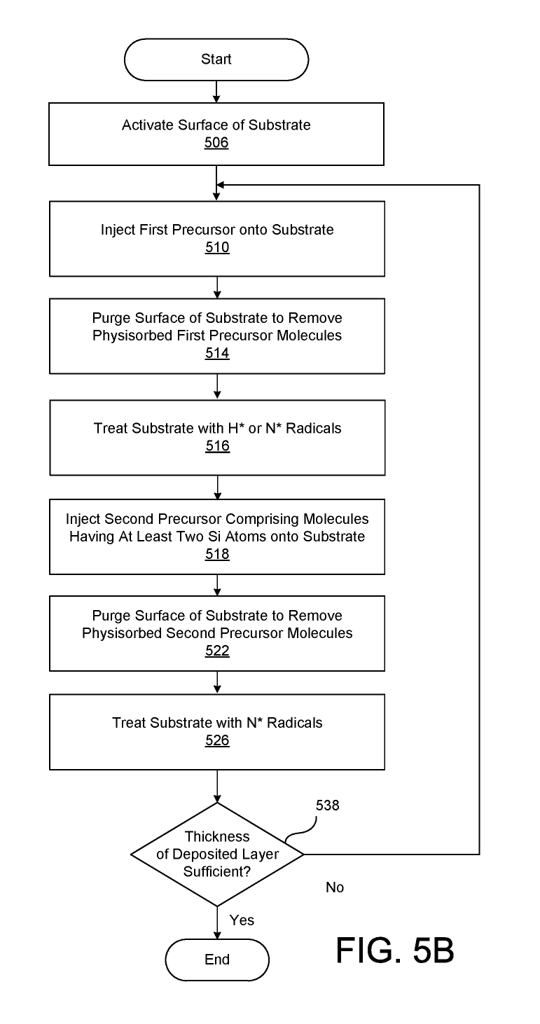

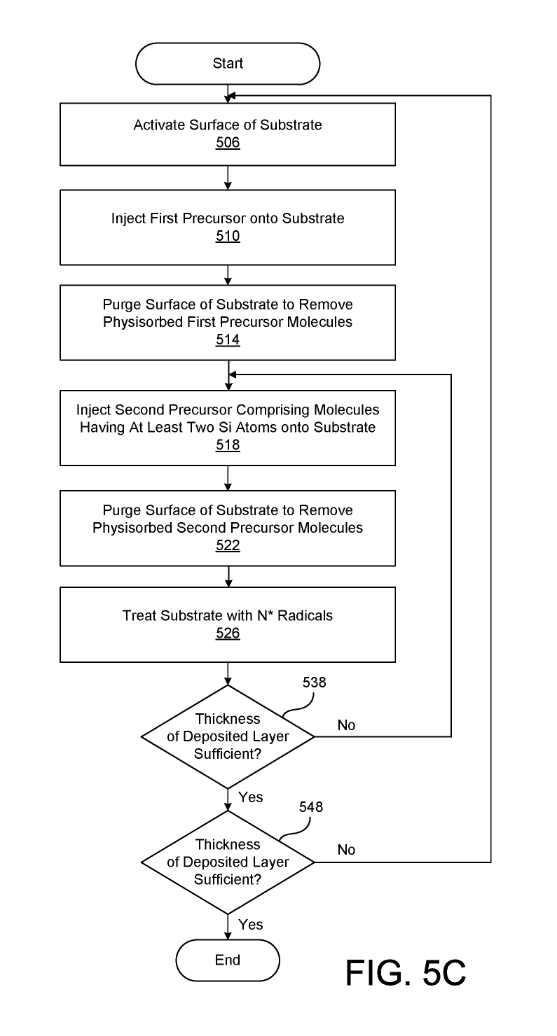

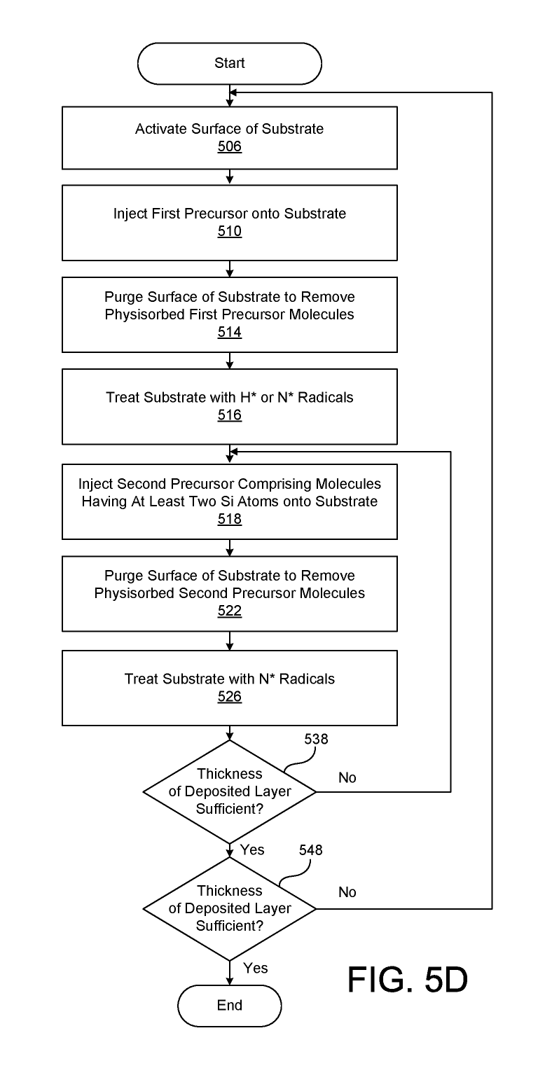

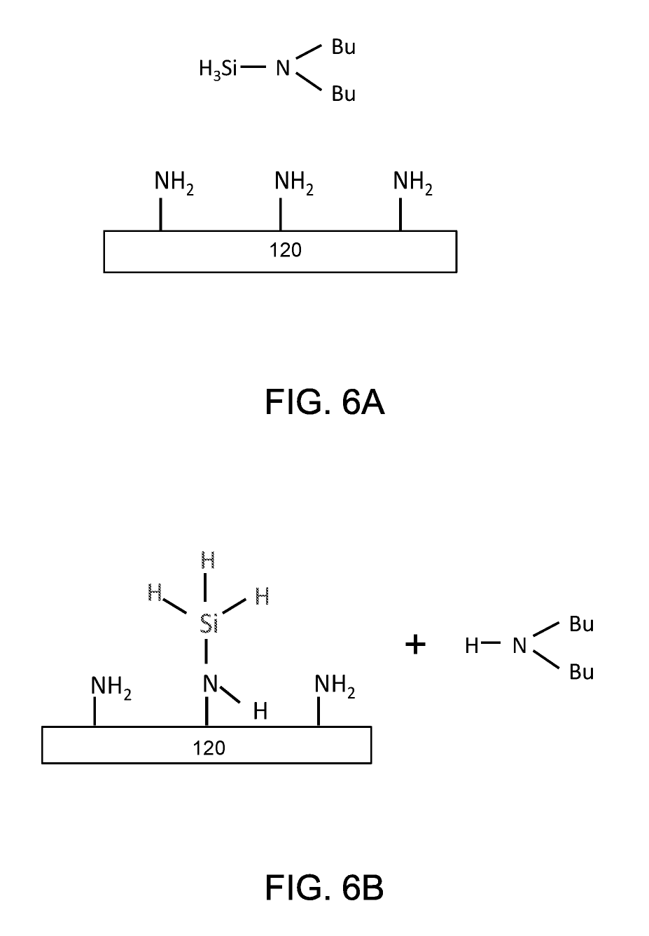

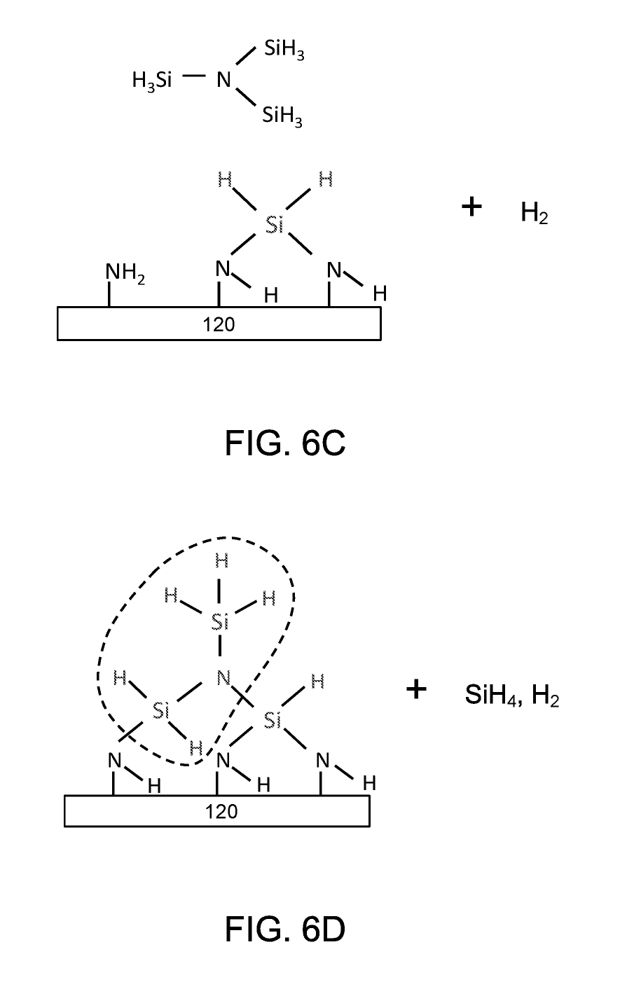

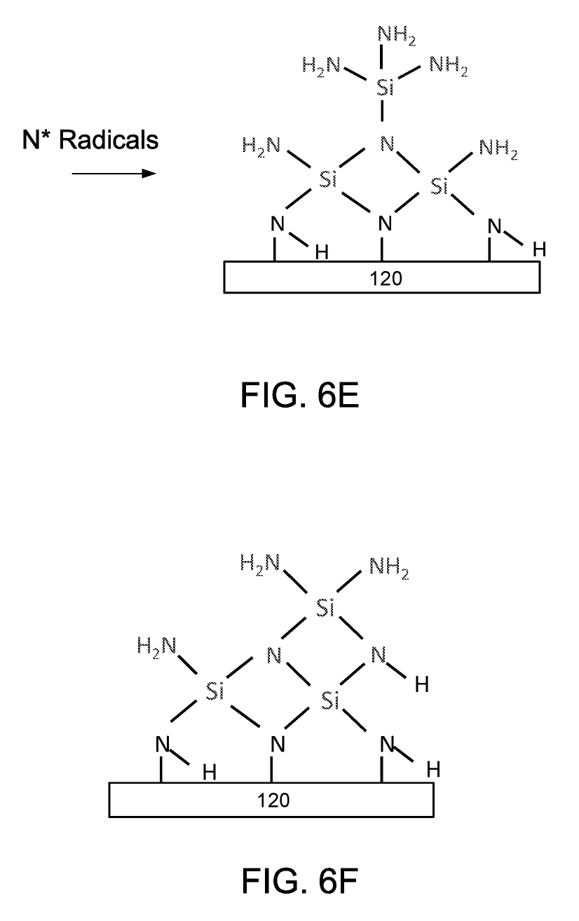

FIG. 5A is a flowchart illustrating deposition of silicon nitride layers using an ALD process, according to one embodiment. FIGS. 6A through 6F are conceptual diagrams illustrating materials deposited on the substrate when the substrate undergoes processing steps for performing ALD using di(sec-butylamino)silane (DSBAS) as the first precursor and trisilylamine (TSA) as the second precursor, according to the embodiment of FIG. 5A. The following embodiments are described with reference to using di(sec-butylamino)silane (DSBAS) as a first precursor and trisilylamine (TSA) as a second precursor, but different combinations of silicon-containing precursors may be used to deposit one or more silicon nitride layers.

First, the surface of the substrate 120 is exposed to at least one of Ar*, H* and N* radicals to remove organic contaminants and unnecessary surface layers, such as native oxide, from the substrate. The radicals are also used to activate 506 the surface of the substrate by breaking surface layer molecular bonds to populate functional sites, for example, with amine groups, or nucleation sites to enhance adsorption of precursor molecules. Referring to FIG. 6A, the surface of the substrate 120 is covered with amine functional groups —NH₂ to facilitate subsequent reactions with the first precursor.

The first precursor (e.g., DSBAS) is injected 510 onto the substrate 120 by injector 136A through the pipe 416 while the substrate 120 passes below injector 136A, as shown in FIGS. 4A and 6A. The first precursor is a silicon-containing compound with a higher sticking coefficient or higher reactivity than the second precursor. The first precursor may have a lower vapor pressure than the second precursor. The sticking coefficient indicates the probability that a molecule (atom) that impinges on the surface adsorbs to the surface. In general, compounds with high sticking coefficients correlate to those with low vapor pressures, and the sticking coefficient decreases with increasing substrate temperature and gas (precursor gas, particles including molecules and atoms) temperature. The sticking coefficient is a function of gas temperature, and at extremely low gas temperatures, the incident particles (molecules or atoms) find it difficult to excite phonons in the lattice, resulting in a small sticking coefficient. When the thermal energy approaches the typical phonon energy, phonon excitation occurs and sticking of the incident particles is more probable. Since sticking of heavy particles (molecules or atoms) depends strongly on the nature of the surface, radical exposure of the surface of the substrate or activating 506 the surface of the substrate enhances the adsorption of precursors and results in better step coverage or conformality.

Consequently, when the first precursor is injected 510, silicon atoms or silane groups from the first precursor (e.g., DSBAS) are adsorbed onto the functional sites of the substrate as a result of activating 506 the surface of the substrate. The functional sites include nitrogen atoms from amine groups, as shown in FIG. 6B, or other highly reactive sites on the surface of the substrate 120. When the first precursor is DSBAS, one molecule of dibutylamine H—N—Bu₂is generated as byproduct and is discharged through the communication channel (not shown) and the exhaust portion 440, along with excess DSBAS. If the substrate 120 is exposed to another precursor, a different byproduct than dibutylamine H—N—Bu₂ may be formed.

The butyl groups in DSBAS may be substituted with other alkyl groups to form the first precursor. Subsequently, a byproduct H—N—R₂ is formed, where R is any alkyl group. The first precursor may additionally include, for example, tris(dimethylamino)silane (3DMAS), bis(diethylamino)silane (BDEAS), bis(tertiery-butylamino)silane (BTBAS), diisopropylaminosilane (DiPAS) or di(sec-butylamino)silane (DSBAS).

As the substrate 120 passes below injector 136B, the substrate 120 is purged 514 to partially or entirely remove physisorbed first precursor molecules from the surface of the substrate 120 while retaining chemisorbed first precursor molecules on the surface of the substrate 120 by injector 136B. The purge gas may include at least one of Ar, H₂, N₂ and NH₃ gas or a combination thereof. Meanwhile, the chemisorbed silane group or silicon atom on the surface of the substrate may react with other amine groups on the surface and produce hydrogen gas H₂ as a byproduct, as shown in FIG. 6C. Removed physisorbed first precursor molecules and other byproducts are discharged through the exhaust portion 442, along with excess purge gas.

As the substrate 120 passes below injector 136C, the second precursor (e.g., TSA) is injected 518 onto the substrate 120 by injector 136C through the pipe 424, as shown in FIGS. 4A and 6C. The second precursor described herein refers to material whose molecules each have at least two silicon atoms. One of many advantages of using the second precursor is that faster deposition rates of silicon nitride can be achieved. The second precursor may include, for example, bis(trimethylsilyl)carbodiimde (BTSCDI), hexamethyldisilazane (HMDS) trisilylamine (TSA), Trisilylamino-diethylsilane (TSADES), Bis(dimethylaminomethylsilyl) (methylsilyl) amine (BDMAMS-MSA: C₇H₂₅N₃Si₃), Bis(dimethylaminomethylsilyl) (trimethylsilyl) amine (BDMAMS-TMSA: C₉H₂₉N₃Si₃), disilane (Si₂H₆), or trisilane (Si₃H₈).

When the second precursor is TSA, the TSA molecules react with the chemisorbed DSBAS and produce more than two molecules of silicon compounds on the surface of the substrate, as shown in FIG. 6D. One molecule of silane SiH₄ and one molecule of hydrogen gas H₂ are generated as byproduct and are discharged through the exhaust portion 444, along with excess TSA.

As the substrate 120 passes below injector 136D, the substrate 120 is purged 522 to partially or entirely remove physisorbed second precursor molecules from the surface of the substrate 120 by injector 136D. The purge gas may include at least one of Ar, H₂, N₂ and NH₃ gas or a combination thereof. Removed physisorbed second precursor molecules and other byproducts are discharged through the exhaust portion 446, along with excess purge gas.

As the substrate 120 passes below the radical reactor 136E, the surface of the substrate 120 is treated 526 with nitrogen radicals N* by radical reactor 136E to form a mono or multiple atomic layers per radical exposure. The nitrogen radicals N* may be formed from a gas including at least one of N₂, (N₂+H₂), (N₂+Ar), (N₂+NH₃), NH₃, (NH₃+H₂) and (NH₃+Ar) gas or a combination thereof. The gas is injected through pipe 412 and nitrogen radicals N* are generated by applying a voltage across the electrode 426 and the body of the reactor 136E. As a result, silicon nitride SiₓN_{y} is formed on the substrate, as shown in FIG. 6E, and the chemisorbed nitrogen atoms may further react with deposited material on the surface to form a high quality silicon nitride film, as shown in FIG. 6F. Excess gas, radicals and byproducts are discharged through the exhaust portion 448.

The substrate 120 may be purged (if necessary) to partially or entirely remove excess radicals by another injector (not shown).

The thickness of the deposited silicon nitride layer is determined 538. If the thickness of the silicon nitride layer is sufficient (i.e., exceeds a threshold thickness), the process terminates. In one embodiment, if the thickness of the silicon nitride layer is insufficient (i.e., does not exceed a threshold thickness), the process returns to injecting 510 the first precursor onto the substrate 120. In another embodiment, if the thickness of the silicon nitride layer is insufficient, the process returns to activating 506 the surface of the substrate 120 instead of returning to injecting 510 of the first precursor.

The process of FIG. 5A can be modified to include additional steps or eliminate steps from what is illustrated. For example, the first precursor may be injected 510 onto the surface of the substrate without activating 506 the surface of the substrate. In addition, one or more of the purging operations 514, 522 for removing excess physisorbed first or second precursors from the surface of the substrate may be omitted.

FIG. 5B is a flowchart illustrating deposition of silicon nitride layers using an ALD process with the process of treating the substrate with hydrogen radicals H* as well as nitrogen radicals N*, according to one embodiment. In the embodiment of FIG. 5B, the substrate 120 is treated 516 with hydrogen radicals H* or nitrogen radicals N* after the substrate 120 is purged 514 to remove physisorbed first precursor molecules, and before the second precursor is injected 518 onto the substrate. The surface of the substrate 120 is treated 516 with H* radicals or nitrogen radicals N* by injector 136H through the pipe 413 while the substrate 120 passes below injector 136H. The H* radicals may change the chemical properties of the chemisorbed first precursor via breaking the ligand(s) from the first precursor molecule or reacting the ligand(s) with H* radicals. The hydrogen radicals H* may be formed of at least one or a combination of H₂, H₂+Ar, N₂+H₂, NH₃, N₂+NH₃ gas.

As the substrate 120 passes below injector 136C, the second precursor (e.g., TSA) is injected onto the substrate 120 that is in a more reactive state than that of the embodiment in FIG. 5A, and more second precursor molecules may be adsorbed onto the surface of the substrate 120. As the substrate 120 passes below the radical reactor 136E, the surface of the substrate 120 is treated 526 with nitrogen radicals N* by radical reactor 136E to form multiple atomic layers per radical exposure. As a result of injecting these materials in sequence, a silicon nitride layer can be deposited on the substrate 120 with higher deposition rate than the film processed in the embodiment of FIG. 5A, and higher film qualities with higher density can be obtained.

The thickness of the deposited silicon nitride layer is determined 538. If the thickness of the silicon nitride layer is sufficient (i.e., exceeds a threshold thickness), the process terminates. In one embodiment, if the thickness of the silicon nitride layer is insufficient (i.e., does not exceed a threshold thickness), the process returns to injecting 510 the first precursor onto the substrate 120. In another embodiment, if the thickness of the silicon nitride layer is insufficient, the process returns to activating 506 the surface of the substrate 120 instead of returning to injecting 510 of the first precursor.

Similar to FIG. 5A, it is to be understood that the process of FIG. 5B can be modified to include additional steps or eliminate steps from what is illustrated. For example, the first precursor may be injected 510 onto the surface of the substrate without activating 506 the surface of the substrate. In addition, one or more of the purging operations 514, 522 for removing excess physisorbed first or second precursors from the surface of the substrate may be omitted.

FIG. 5C is a flowchart illustrating deposition of silicon nitride layers using an ALD process, according to another embodiment. The embodiment shown in FIG. 5C is includes similar steps to that of FIG. 5A, but the steps of injecting the second precursor, purging the substrate to remove the physisorbed second precursor molecules, and treating the substrate with nitrogen radicals N* are repeated for a predetermined number of times or until the thickness of the deposited layer reaches a predetermined value.

Moreover, in the embodiment of FIG. 5C, an aluminum (Al)-containing precursor, such as Trimethylaluminum (TMA: (CH₃)₃Al), can be injected 510 as the first precursor for the nucleation or seed layer formation, along with any of the first precursors used in the embodiments of FIGS. 5A and 5B. An Al-containing monolayer can be used for the initial layer for forming multiple layers of (AlN)(SiN)_{n, n=1, 2, 3 . . .} because the Al-containing precursor may provide a better nucleation layer than other Si-containing precursors. Moreover, AlN is a thermally and chemically stable dielectric material, similarly to SiN.

After the substrate is treated 526 with nitrogen radicals N*, a thickness of the deposited layer is determined 538. If the increase in thickness of the silicon nitride layer due to the injection 518 of the second precursor and treatment 526 of nitrogen radicals N* is insufficient, the process may return to injecting 518 the second precursor, purging 522 the surface of the substrate to remove the physisorbed second precursor, and treating 526 the substrate with nitrogen radicals N* repeatedly until the increase in thickness reaches a predetermined value.

The overall thickness of the silicon nitride layer is determined 548. In one embodiment, if the overall thickness of the silicon nitride layer is still insufficient, the process returns to injecting 510 the first precursor onto the substrate 120. In another embodiment, if the thickness of the silicon nitride layer is insufficient, the process returns to activating 506 the surface of the substrate 120 instead of returning to injecting 510 of the first precursor.

FIG. 5D is a flowchart illustrating deposition of silicon nitride layers using an ALD process, according to another embodiment. The embodiment shown in FIG. 5D includes steps similar to those of FIG. 5B, but the steps of injecting the second precursor, purging the substrate to remove the physisorbed second precursor molecules, and treating the substrate with nitrogen radicals N* are repeated for a predetermined number of times or until the thickness of the deposited layer reaches a predetermined value.

Moreover, similarly to the embodiment shown in FIG. 5C, in the embodiment of FIG. 5D, an Al-containing precursor (e.g., TMA) may be injected 510 as the first precursor for formation of the nucleation or seed layer, in addition to the first precursors used in the embodiments of FIGS. 5A and 5B.

After the substrate is treated 526 with nitrogen radicals N*, a thickness of the deposited layer is determined 538. If the increase in thickness of the silicon nitride layer due to the injection 518 of the second precursor and treatment 526 of nitrogen radicals N* is insufficient, the process may return to injecting 518 the second precursor, and proceed to purging 522 the surface of the substrate to remove the physisorbed second precursor, and treating 526 the substrate with nitrogen radicals N* for a number of times until the increase in thickness reaches a predetermined value.

The thickness of the overall silicon nitride layer is determined 548. In one embodiment, if the overall thickness of the silicon nitride layer is still insufficient, the process returns to injecting 510 the first precursor onto the substrate 120. In another embodiment, if the thickness of the silicon nitride layer is insufficient, the process returns to activating 506 the surface of the substrate 120 instead of returning to injecting 510 of the first precursor.

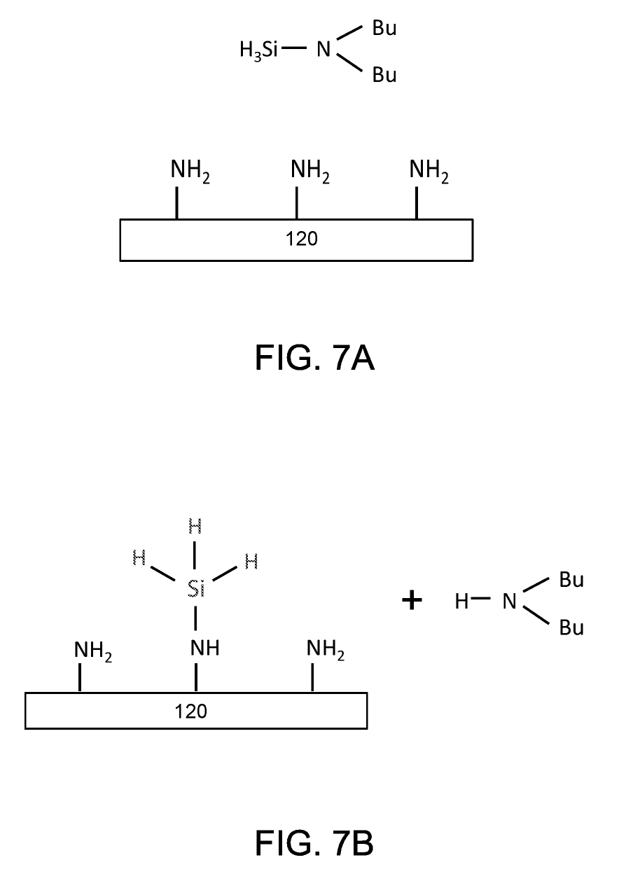

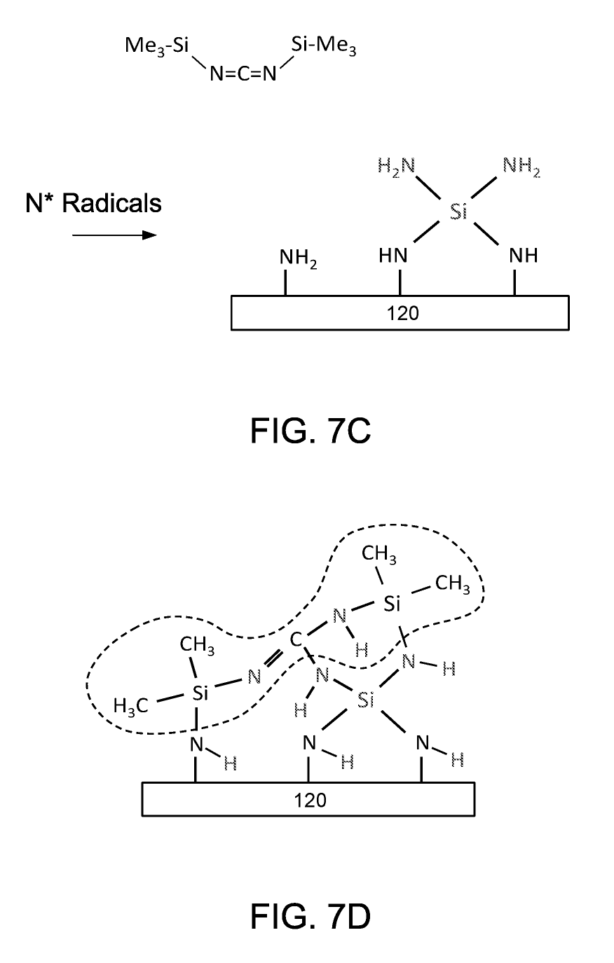

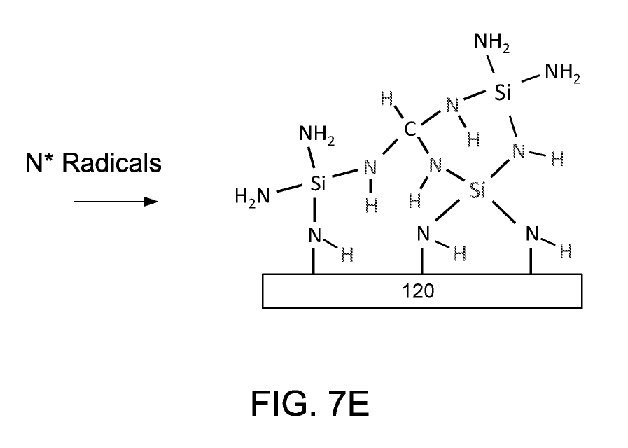

FIGS. 7A through 7E are conceptual diagrams illustrating materials deposited on the substrate when the substrate undergoes processing steps for performing ALD using di(sec-butylamino)silane (DSBAS) as the first precursor and bis(trimethylsilyl)carbodiimde (BTSCDI) as the second precursor, according to another embodiment. FIGS. 7A and 7B illustrate processes corresponding to the process of activating 506 the surface through the process of purging 514 the surface of FIG. 5A described above with reference to the embodiment of FIGS. 6A and 6B (where DSBAS is used as the first precursor), and therefore, the detailed description thereof is omitted for the sake of brevity.

After activating 506 the surface of the substrate, injecting 510 the first precursor (e.g., DSBAS) and purging 514 the surface of the substrate 120, the substrate 120 may additionally be treated with nitrogen radicals N* from N₂ or (N₂+H₂) plasma. BTSCDI is then injected 518 as the second precursor by injector 136C through pipe 424, as shown in FIG. 7C. When the second precursor is BTSCDI, the BTSCDI molecules react with the chemisorbed DSBAS and produce more than two molecules of silicon compounds on the surface of the substrate, as shown in FIG. 7D. Moreover, the carbodiimide molecule reacts with hydrogen in amines such that the C═N carbon double bond is broken to create new carbon single bonds, as shown in FIG. 7D.

The substrate 120 is purged 522 to partially or entirely remove physisorbed second precursor molecules from the surface of the substrate 120 by injector 136D. The purge gas may include at least one of Ar, H₂, N₂ and NH₃ gas or a combination thereof. Removed physisorbed second precursor molecules and other byproducts are discharged through the exhaust portion 446, along with excess purge gas.

The surface of the substrate 120 is treated 526 with nitrogen radicals N* by radical reactor 136E to form multiple atomic layers per radical exposure. The nitrogen radicals N* may be formed from a gas including at least one of N₂, (N₂+H₂), (N₂+Ar), NH₃, (NH₃+H₂), NH₃+N₂, and (NH₃+Ar) gas of a combination thereof. The gas is injected through pipe 412 and nitrogen radicals N* as well as other radicals are generated by applying a voltage across the electrode 426 and a body of the reactor 136E. As a result, silicon nitride SiₓN_{y} is formed on the substrate, as shown in FIG. 7E. Excess gas, radicals and byproducts are discharged through the exhaust portion 448.

The substrate 120 may be purged (if necessary) to partially or entirely remove excess radicals by another injector (not shown).

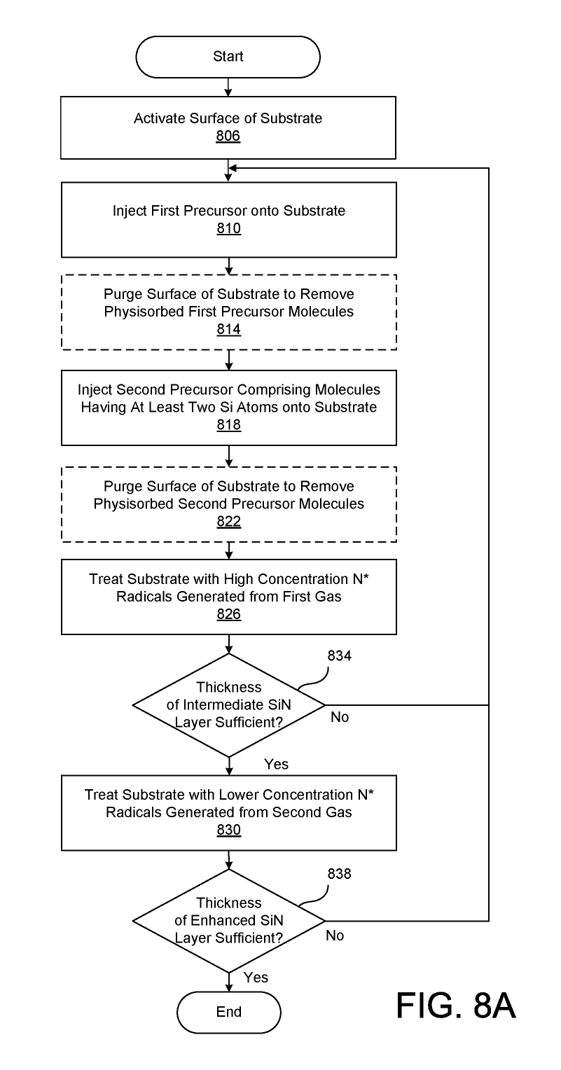

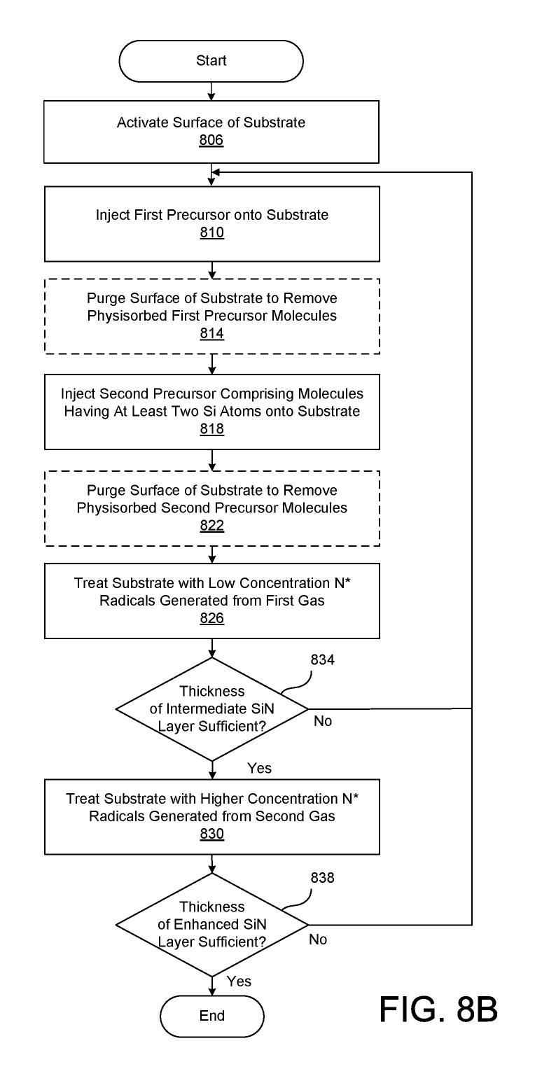

FIG. 8A is a flowchart illustrating deposition of silicon nitride layers using an ALD process, according to another embodiment. The following embodiments are described primarily with reference to using di(sec-butylamino)silane (DSBAS) as a first precursor and trisilylamine (TSA) as a second precursor, but different combinations of silicon-containing precursors may be used to deposit one or more silicon nitride layers.

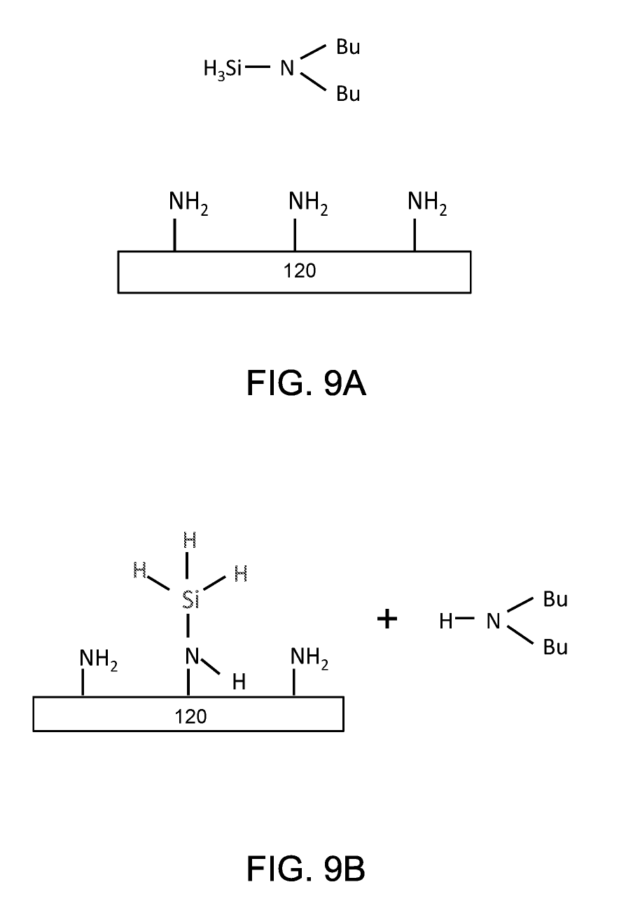

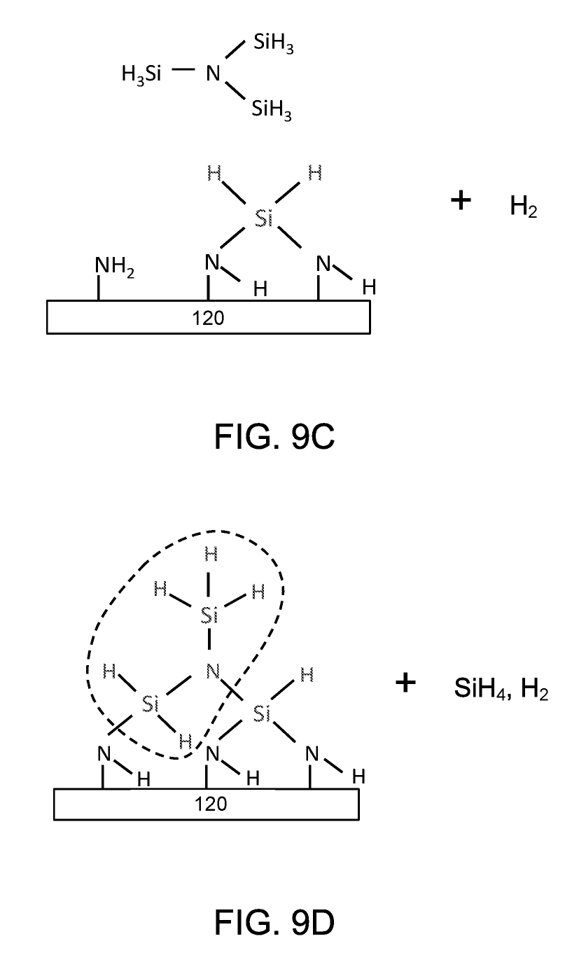

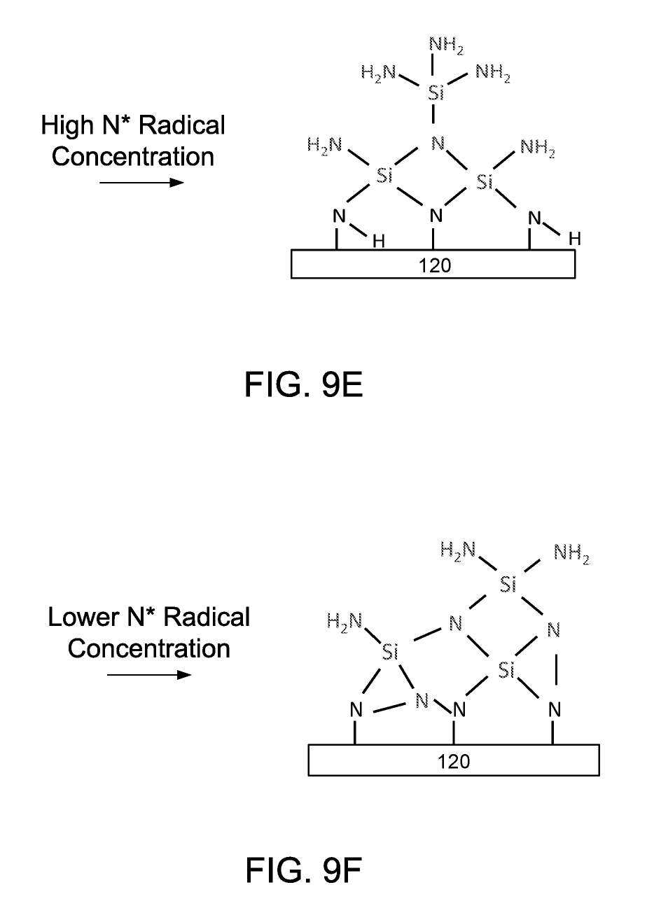

First, the surface of the substrate 120 is exposed to at least one of Ar*, H* and N* radicals to remove organic contaminants and unnecessary surface layers, such as native oxide, from the substrate. The radicals are also used to activate 806 the surface of the substrate by breaking surface layer molecular bonds to populate functional sites, for example, with amine groups, to enhance adsorption of precursor molecules. Referring to FIG. 9A, the surface of the substrate 120 is covered with amine functional groups —NH₂ to facilitate subsequent reactions with the first precursor.

As the substrate 120 passes below injector 136A of FIG. B, the first precursor (e.g., DSBAS) is injected 810 onto the substrate by injector 136A through the pipe 416, as shown in FIG. 9A. Consequently, silicon atoms and silane groups from the first precursor (e.g., DSBAS) are adsorbed to the nitrogen atoms from the amine groups attached to the surface of the substrate 120, as shown in FIG. 9B. When the silicon-containing seed precursor is DSBAS, one molecule of dibutylamine H—N—Bu₂is generated as byproduct and is discharged through the exhaust portion 440, along with excess DSBAS. If the substrate 120 is exposed to another precursor, a byproduct other than dibutylamine H—N—Bu₂ may be formed.

DSBAS is one example of the first precursor that can be used in the embodiment of FIG. 8A. Examples of first precursors that can be used in the embodiment of FIG. 8A are described above with reference to the embodiment of FIG. 5A, and therefore, the detailed description thereof is omitted for the sake of brevity. As the substrate 120 passes below injector 136B of FIG. 4B, the substrate 120 may be purged 814 to partially or entirely remove physisorbed first precursor molecules from the surface of the substrate 120 while retaining chemisorbed first precursor molecules on the surface of the substrate 120 by injector 136B. The purge gas may include at least one of Ar, H₂, N₂ and NH₃ gas or a combination thereof. Meanwhile, the chemisorbed silane group or silicon atom on the surface of the substrate may react with other amine groups on the surface and produce hydrogen gas H₂ as a byproduct, as shown in FIG. 9C. Removed physisorbed first precursor molecules and other byproducts are discharged through the exhaust portion 442, along with excess purge gas.

After activating 806 the surface of the substrate, injecting 810 the first precursor (e.g., DSBAS) and purging 814 the surface of the substrate 120, the substrate 120 may additionally be treated with nitrogen radicals N* from N₂ or (N₂+H₂) plasma or with hydrogen radicals H*. As the substrate 120 passes below injector 136C of FIG. 4B, the second precursor (e.g., TSA) is injected 818 onto the substrate 120 by injector 136C through the pipe 424. The second precursor described herein refers to material whose molecules each have at least two silicon atoms. When the second precursor is TSA, the TSA molecules react with the chemisorbed DSBAS and produce more than two molecules of silicon compounds on the surface of the substrate, as shown in FIG. 9D. One molecule of silane SiH₄ and hydrogen gas H₂ is generated as byproduct and is discharged through the exhaust portion 444, along with excess TSA.

Examples of second precursors that can be used in the embodiment of FIG. 8A are described above with reference to the embodiment of FIG. 5A, and therefore, the detailed description thereof is omitted for the sake of brevity.

The substrate 120 then may be purged 822 to partially or entirely remove physisorbed second precursor molecules from the surface of the substrate 120 by another injector (not shown) after reactor 136C and before reactor 136F. The purge gas may include at least one of Ar, H₂, N₂ and NH₃ gas or a combination thereof

As the substrate passes below radical reactor 136F, the surface of the substrate 120 is treated 826 with high concentration nitrogen radicals N* by radical reactor 136F. The high concentration nitrogen radicals N* may be formed from a first gas including at least one of N₂, (N₂+H₂), (N₂+Ar), NH₃, (NH₃+H₂), NH₃+H₂, and (NH₃+Ar) gas or a combination thereof (e.g., 80% N₂ and 20% Ar). The first gas is injected through pipe 414 and high concentration nitrogen radicals N* are generated by applying a voltage across the electrode 456 and the body of the reactor 136F. As a result, an intermediate silicon nitride SiₓN_{y} layer is formed on the substrate 120, as shown in FIG. 9E. Excess gas, radicals and byproducts are discharged through the exhaust portion 447.

The substrate 120 may be purged (if necessary) to partially or entirely remove excess radicals by another injector (not shown).

The thickness of the deposited intermediate silicon nitride layer is determined 834. If the thickness of the intermediate silicon nitride layer is not sufficient (i.e., does not exceed a threshold thickness), the process returns to injecting 810 the first precursor onto the substrate until a sufficient thickness is reached. While repeating injecting 810 through treating 826 due to insufficient thickness of the intermediate silicon nitride layer, radical reactor 136G may be turned off.

If the thickness of the deposited intermediate silicon nitride layer is sufficient, radical reactor 136G is turned on and the surface of the substrate 120 is treated 830 with lower concentration nitrogen radicals N* by radical reactor 136G. The lower concentration nitrogen radicals N* may be formed from a second gas including at least one of (N₂+H₂), (N₂+Ar), (NH₃+H₂), NH₃+N₂, and (NH₃+Ar) gas or a combination thereof. The second gas has a lower concentration of nitrogen gas and/or nitrogen species than the first gas. The second gas is injected through pipe 415 and lower concentration nitrogen radicals N* are generated by applying a voltage across the electrode 458 and body of the reactor 136G. As a result, an enhanced silicon nitride SiₓN_{y} layer is formed on the substrate 120, as shown in FIG. 9F. Excess gas, radicals and byproducts are discharged through the exhaust portion 449.

During treating 830 of the substrate, nitrogen radicals N* are introduced with other species such as Ar* and H* to break unstable surface layer bonds and also Si—H and Si—N—H bonds that lead to altered surface chemistry and stoichiometry of the silicon nitride layer. By introducing (N*+Ar*) or (N*+H*) radicals onto the intermediate silicon nitride layer, the Si—H and Si—N—H bonds are broken and nitrogen radicals N* attach to the dangling bonds (or dangling sites), resulting in a reduction of H and N—H contents in the enhanced silicon nitride film. The enhanced silicon nitride layer was found to have lower etch rates in diluted hydrofluoride (DHF) compared to the intermediate silicon nitride layer.

Subsequently, the thickness of the deposited enhanced silicon nitride layer is determined 838. If the thickness of the enhanced silicon nitride layer is sufficient (i.e., does not exceed a threshold thickness), the process returns to injecting 810 the first precursor onto the substrate until a sufficient thickness is reached.

The process of FIG. 8A can be modified to include additional steps or eliminate steps from what is illustrated. For example, the first precursor may be injected 810 onto the surface of the substrate without activating 806 the surface of the substrate. In addition, one or more of the purging operations 814, 822 for removing excess physisorbed first or second precursors from the surface of the substrate may be omitted.

FIG. 8B is a flowchart illustrating a method of depositing one or more silicon nitride layers onto a substrate, according to another embodiment. The embodiment shown in FIG. 8B includes steps similar to those of FIG. 8A, but the substrate is treated 826 with low concentration of nitrogen radicals N* before being treated 830 with high concentration of nitrogen radicals N*.

Specifically, after injecting 818 the second precursor, the substrate passes below the radical reactor 136G. The surface of the substrate 120 is treated 826 with low concentration nitrogen radicals N* formed from a first gas including at least one of N₂, (N₂+H₂), (N₂+Ar), NH₃, (NH₃+H₂), NH₃+N₂, and (NH₃+Ar) gas or a combination thereof.

The first gas is injected through pipe 415 and low concentration nitrogen radicals N* are generated by applying a voltage across the electrode 458 and the body of the reactor 136G. As a result, an intermediate silicon nitride SiₓN_{y} layer is formed on the substrate 120. Excess gas, radicals and byproducts are discharged through the exhaust portion 449.

After determining 834 whether the thickness of the deposited intermediate silicon nitride layer is sufficient, the radical reactor 136F is turned on and the surface of the substrate 120 is treated 830 with higher concentration nitrogen radicals N* by radical reactor 136F. The higher concentration nitrogen radicals N* may be formed from a second gas including at least one of (N₂+H₂), (N₂+Ar), (NH₃+H₂), NH₃+N₂, and (NH₃+Ar) gas or a combination thereof. The second gas has a higher concentration of nitrogen gas and/or nitrogen species than the first gas. The second gas is injected through pipe 414 and higher concentration nitrogen radicals N* are generated by applying a voltage across the electrode 456 and body of the reactor 136F. As a result, an enhanced silicon nitride Si,(N_{y} layer is formed on the substrate 120. Excess gas, radicals and byproducts are discharged through the exhaust portion 447.

For example, instead of forming the intermediate silicon nitride layer by treating the substrate 120 with high concentration of nitrogen radicals N* as shown in FIG. 9E, the intermediate silicon nitride layer may be formed by treating the substrate 120 with a low concentration of nitrogen radicals N*. Also, instead of forming the enhanced silicon nitride layer by treating the intermediate silicon nitride layer substrate 120 with low concentration of nitrogen radicals N* as shown in FIG. 9F, the enhanced silicon nitride layer may be formed by treating the substrate 120 with a high concentration of nitrogen radicals N*.

Although the present invention has been described above with respect to several embodiments, various modifications can be made within the scope of the disclosure. Accordingly, the disclosure described above is intended to be illustrative, but not limiting.

1. A method for depositing one or more silicon nitride layers onto a substrate, the method comprising:
injecting a first precursor comprising Si onto a surface of the substrate, the first precursor having a first sticking coefficient;
injecting a second precursor comprising molecules each having at least two Si atoms onto the surface of the substrate to deposit the one or more silicon nitride layers onto the substrate by reaction between the first precursor injected onto the substrate and the second precursor, the second precursor having a second sticking coefficient lower than the first sticking coefficient; and
treating the substrate with nitrogen radicals N* formed from a first gas after injecting the second precursor, where the nitrogen radicals N* formed from the first gas interact with the first precursor and the second precursor to deposit the one or more silicon nitride layers onto the substrate.

2. The method of claim 1, further comprising treating the substrate with nitrogen radicals N* formed from a second gas after treating the substrate with nitrogen radicals N* formed from the first gas, concentration of nitrogen species in the first gas higher than concentration of nitrogen species in the second gas.

3. The method of claim 1, wherein the first gas comprises at least one of N₂, (N₂+H₂), (N₂+Ar), and (N₂+NH₃) gas.

4. The method of claim 1, wherein the first precursor comprises tris(dimethylamino)silane (3DMAS), bis(diethylamino)silane (BDEAS), bis(tertiery-butylamino)silane (BTBAS), diisopropylaminosilane (DiPAS) or di(sec-butylamino)silane (DSBAS).

5. The method of claim 1, wherein the second precursor comprises bis(trimethylsilyl)carbodiimde (BTSCDI), hexamethyldisilazane (HMDS) or trisilylamine (TSA), Trisilylamino-diethylsilane (TSADES), Bis(dimethylaminomethylsilyl) (methylsilyl) amine (BDMAMS-MSA: C₇H₂₅N₃Si₃), Bis(dimethylaminomethylsilyl) (trimethylsilyl) amine (BDMAMS-TMSA: C₉H₂₉N₃Si₃), disilane (Si₂H₆), or trisilane (Si₃H₈).

6. The method of claim 1, further comprising purging the surface of the substrate with inert gas to remove at least one of physisorbed first precursor molecules or the second precursor molecules.

7. The method of claim 1, further comprising treating the substrate with hydrogen radicals H* formed from a second gas before injecting the second precursor and after injecting the first precursor.

8. The method of claim 7, wherein the second gas comprises at least one of H₂ and (H₂+Ar) gas.

9. The method of claim 1, further comprising exposing the surface of the substrate to radicals formed from a second gas to activate the surface of the substrate before injecting the first precursor.

10. The method of claim 9, wherein the second gas comprises at least one of Ar, H₂, NH₃ and N₂ gas.

11. The method of claim 1, further comprising treating the substrate with nitrogen radicals N* formed from a second gas before injecting the second precursor and after injecting the first precursor.

12. The method of claim 1, further comprising treating the substrate with nitrogen radicals N* formed from a second gas after treating the substrate with nitrogen radicals N* formed from the first gas, concentration of nitrogen species in the first gas lower than concentration of nitrogen species in the second gas.

13. The method of claim 1, wherein the first gas comprises at least one of (N₂+H₂), (N₂+Ar), NH₃, (NH₃+H₂), NH₃+N₂, and (NH₃+Ar) gas.

14. An apparatus for depositing one or more silicon nitride layers onto a substrate, the apparatus comprising:
a first injector having a first reaction chamber opening towards a surface of a substrate;
a moving actuator configured to cause a relative movement between the substrate and the first injector;
a second injector on a path of the relative movement, the second injector having a second reaction chamber opening towards the surface of the substrate;
a first radical reactor on the path of the relative movement; and
a controller causing the first injector to inject a silicon-containing first precursor onto the substrate to cause adsorption of silicon atoms of the first precursor having a first sticking coefficient onto the substrate the controller further causing the second injector to inject a second precursor comprising molecules each having at least two Si atoms onto the surface of the substrate to deposit the one or more silicon nitride layers onto the substrate by reaction between the first precursor injected onto the substrate and the second precursor, the second precursor having a second sticking coefficient lower than the first sticking coefficient, the controller further causing the first radical reactor to generate and inject nitrogen radicals N* formed from a first gas onto the substrate after injecting the second precursor, the nitrogen radicals N* formed from the first gas interacting with the first precursor and the second precursor to deposit the one or more silicon nitride layers onto the substrate.

15. The apparatus of claim 14, further comprising a second radical reactor on the path of the relative movement, wherein the controller further causes the second radical reactor to generate and inject nitrogen radicals N* generated from a second gas onto the substrate after injecting the second precursor and before injecting the nitrogen radicals N* generated from the first gas to deposit one or more intermediate silicon nitride layers onto the substrate, concentration of nitrogen species in the second gas being higher than concentration of nitrogen species in the first gas.

16. The apparatus of claim 14, further comprising a second radical reactor on the path of the relative movement, wherein the second radical reactor further generates and injects hydrogen radicals H* generated from a second gas onto the substrate after injecting the first precursor and before injecting the second precursor.

17. The apparatus of claim 14, wherein the first injector, the second injector, and the radical reactor are sequentially placed in tandem adjacent to each other.

18. The apparatus of claim 14, further comprising an exhaust portion in fluid communication with the first injector and configured to discharge at least an excess portion of the first precursor.

19. The apparatus of claim 14, wherein the radical reactor comprises a body and an electrode extending within the body, wherein voltage difference is applied between the body and the electrode to generate the nitrogen radicals N* from the first gas.

20. A method for depositing one or more silicon nitride layers onto a substrate, the method comprising:
injecting a first precursor onto a surface of the substrate for forming a seed layer;
injecting a second precursor comprising molecules each having at least two Si atoms onto the surface of the substrate to deposit the one or more silicon nitride layers onto the substrate by reaction between the first precursor injected onto the substrate and the second precursor; and
treating the substrate with nitrogen radicals N* formed from a first gas after injecting the second precursor, wherein the nitrogen radicals N* formed from the first gas interact with the first precursor and the second precursor to deposit the one or more silicon nitride layers onto the substrate.

21. The method of claim 20, further comprising repeating the injecting of the second precursor and the treating of the substrate with the nitrogen radicals N* formed from the first gas until a pre-determined thickness of the one or more silicon nitride layers is reached.

22. The method of claim 20, wherein the first precursor contains aluminum (Al).

23. The method of claim 22, wherein the first precursor is Trimethylaluminum.
